(19) United States
(12) Patent Application Publication
(10) Pub. No.: US 2007/0229132 A1
(43) Pub. Date: Oct. 4, 2007

(54) SCANNABLE DOMINO LATCH REDUNDANCY FOR SOFT ERROR RATE PROTECTION WITH COLLISION AVOIDANCE

(76) Inventors: Sam Gat-Shang Chu, Round Rock, TX (US); Peter J. Klim, Austin, TX (US); Michael Ju Hyeok Lee, Austin, TX (US); Jose Angel Paredes, Austin, TX (US)

Correspondence Address: IBM CORP (YA);C/O YEE & ASSOCIATES PC, P.O. BOX 802333, DALLAS, TX, 75380, US

(21) Appl. No.: 11/277,691

(22) Filed: Mar. 28, 2006

(51) Int. Cl. H03K 3/00

(52) U.S. Cl. 327/218

(57) ABSTRACT

A latch is described that provides soft error rate protection with integrated scan capability and collision avoidance. The latch has a latch output node and a first, second, and third sublatches. Each sublatch has a respective input circuitry, output node, and feedback circuitry coupled to the output node for reinforcing an output signal of the sublatch. Each sublatch is operable to receive a data signal at its input circuitry and responsively generate a binary-state output signal on its output nodes. The first and second output nodes such that, if an output of the third sublatch changes, the first and second sublatches force the third sublatch to have a same output. This “forced” change reduces the soft error rate in the latch and the output signal of the latch output node is restored without the sublatches colliding.

### BACKGROUND OF THE INVENTION

1. Field of the Invention

The present invention relates generally to latch circuitry. More specifically, the present invention relates to a domino latch redundancy circuitry for soft error rate protection with integrated scan capability and collision avoidance.

2. Description of the Related Art

Various latching circuits are known for isolating logic circuitry stages, such as for ensuring orderly evaluation without corrupting data from one logic stage to the next, for avoiding races, and for other timing purposes. In complicated logic circuitry, such as that of a microprocessor or an application specific integrated circuit, it is known to “scan” data in and out of the logic circuitry latches in order to verify proper operation of the circuitry. It is also known to integrate scanning capability into latches.

Domino logic latching circuits are known in the art. For example, latch circuit 100 of FIG. 1 includes an input stage 110 and a feedback stage 120. In FIG. 1, it is assumed that the data signal D_B comes from a preceding domino logic stage. During an evaluate phase, the clock signal goes high and the data signal D_B is held high or driven low by the preceding domino logic stage. With the clock signal high, latch circuit 100 permits the data signal to drive its latch node 121 high or low. Then, during a precharge phase, the data signal D_B goes high and the clock signal CLK goes low. According to the arrangement shown for latch circuit 100, with the data and clock signals in their precharge states, feedback through inverter 122 will hold latch node 121 high or low after evaluation. However, soft errors may corrupt the value of latch node 121.

A domino circuit with parallel redundant latches, such as the prior art latch circuit 200 of FIG. 2, overcomes the limitations inherent in latch circuit 100 of FIG. 1, while at the same time including the ability to scan to the latch nodes. However, latch circuit 200 has the disadvantage that if a soft-error is encountered by the circuits, the parallel source latch nodes 218, 222, and 212 will create a contention condition since inverters 220, 224, and 228 would be sourcing different values to feedback/feed forward node 226.

### SUMMARY OF THE INVENTION

The different aspects of the present invention provide a latch with soft error rate protection with integrated scan capability and collision avoidance. The latch has a latch output node, a first sublatch, a second sublatch, and a third sublatch. The first, second, and third sublatches have respective input circuitry, output nodes, and feedback circuitry coupled to respective output nodes for reinforcing an output signal of the respective sublatches. The sublatches are operable to receive a data signal at their respective input circuitry and responsively generate binary-state output signals on their respective output nodes. The third output node is coupled to the latch output node. The first and second output nodes are also respectively connected such that, if an output of the third sublatch changes, the first and second sublatches force the third sublatch to have a same output as the first and second sublatch. This “forced” change reduces the soft error rate in the latch and the output signal of the latch output node is restored without the first, second, and third sublatches colliding. A number of scanning-mode control switches are also provided, which are coupled to sublatches for scanning data into the latch.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 depicts a domino latch circuit;

FIG. 2 depicts a domino latch circuit with parallel latches;

FIG. 3 depicts a domino latch with integrated scan in accordance with an illustrative embodiment of the present invention; and

FIG. 4 depicts a table of the various output node states and the protection provided by domino sublatches in accordance with an illustrative embodiment of the present invention.

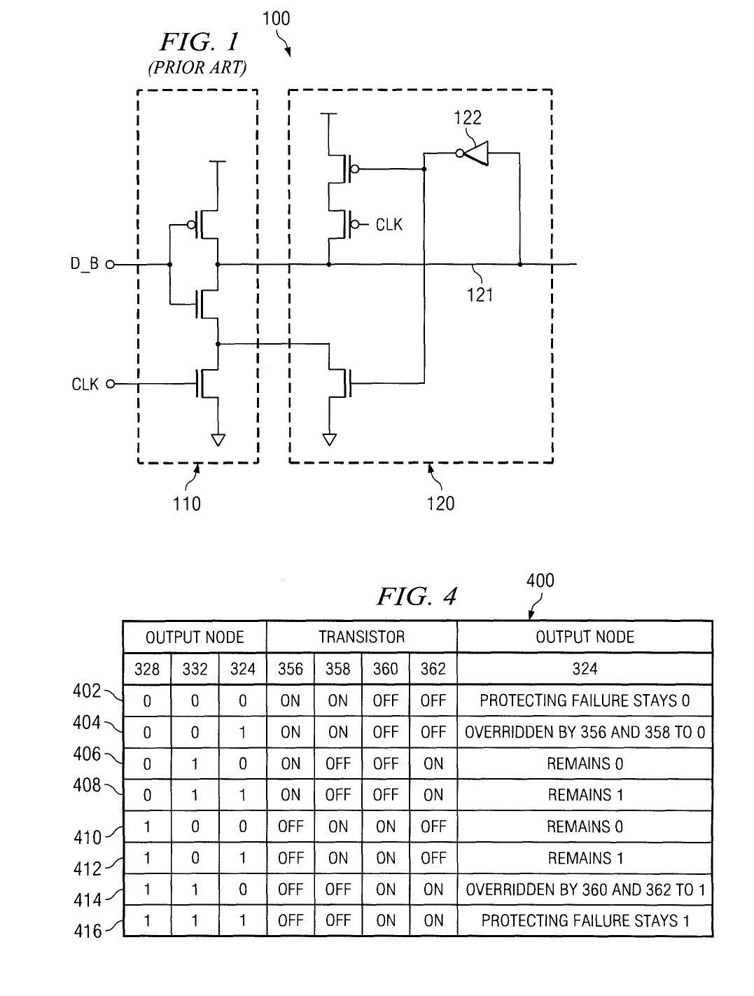

### DETAILED DESCRIPTION OF THE PREFERRED EMBODIMENT

The illustrative embodiments of the present invention provide for domino latch redundancy for soft error rate protection with integrated scan and collision avoidance. The invention, a preferred mode of use, further objectives, and advantages, will best be understood by reference to the following detailed description of an illustrative embodiments read in conjunction with the accompanying drawings.

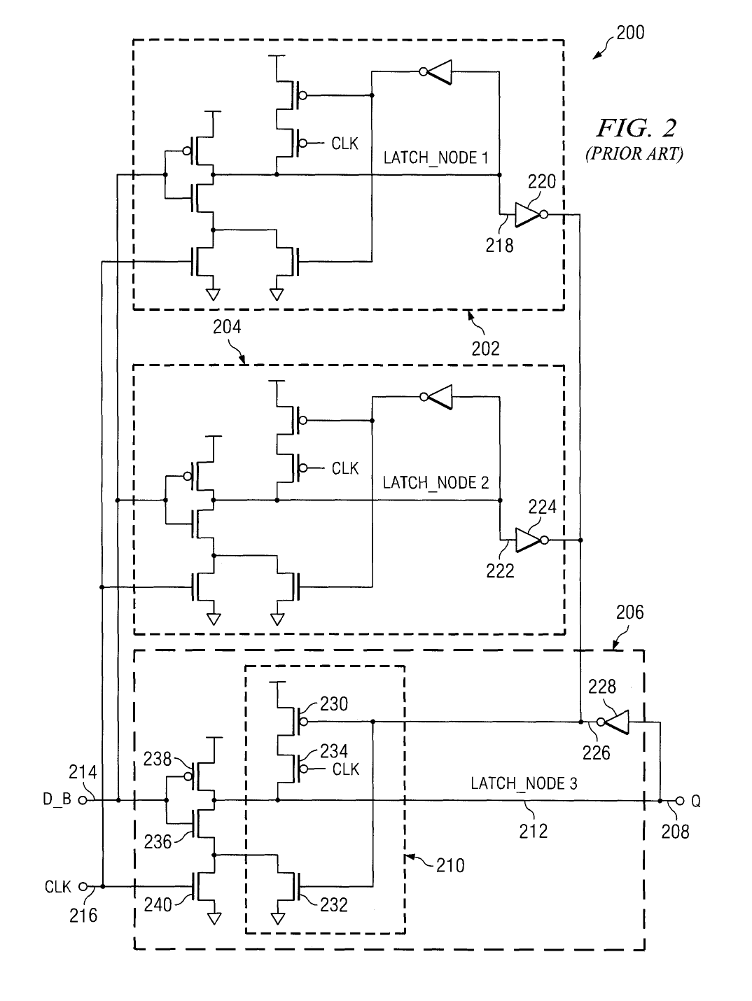

FIG. 2 depicts a parallel domino latch. Domino latch 200 includes three domino latches 202, 204, and 206, which may be referred to herein as “sublatches,” whereas domino latch 200 may be referred to herein as the “overall” latch. Domino latch 200 provides immunity to noise on its output node Q 208.

Domino latch 200 has two independent feed forward domino sublatch circuits, domino sublatch 202 and domino sublatch 204, feeding forward to output domino sublatch 206. Domino latch 200 has only one redundant feed forward circuit because circuitry 210 is employed for both feeding forward the signals from the independent latch node domino sublatches 202 and 204 and feeding back the output signal from output node Q 208. Consequently, circuitry 210 is referred to herein as “feedback/feed forward” circuitry. However, circuitry 210 may also be referred to herein as merely “feedback” circuitry.

More particularly, the two feed forward domino sublatches, domino sublatches 202 and 204, in domino latch 200 are coupled to feedback circuitry 210 of output domino sublatch 206. Output domino sublatch 206 in turn has its output node 212 coupled to domino latch's 200 output node Q 208. Since output node 212 is directly coupled to the overall output node Q 208 with no device interposed there between, it may be said that output node 212 provides the overall output to output node Q 208. Domino sublatch 202 is coupled to data input D_B 214 and clock input CLK 216, for receiving signals of the same name, and its output node 218 provides a latch node that is coupled to feedback/feed forward circuitry 210 via inverter 220. Inverter 220 may be considered to be part of domino sublatch 202, and may accordingly be referred to herein as an output inverter of the domino sublatch 202. Similarly, domino sublatch 204 is coupled to receive the data and clock signals, and its output node 222 provides a latch node that is coupled to feedback/feed forward circuitry 210 via inverter 224. Inverter 224 may be considered to be part of domino sublatch 204, and may accordingly be referred to herein as an output inverter of domino sublatch 204. Domino sublatch 206 is also coupled to receive the data and clock signals.

The internal circuitry of domino sublatch 206 is shown in FIG. 2 to reveal the location of the feed forward connection of the outputs of inverters 220 and 224 to feedback/feed forward node 226 within circuitry 210, and to show the interrelationship and operation of various parts. The binary output signal from output node Q 208 is fed back by feedback/feed forward circuitry 210 through inverter 228, which has its output coupled to feedback/feed forward node 226 that is common to the gates of pull-up transistor 230 and pull-down transistor 232. In this manner, during the precharge interval when the data input D_B 214 is high and the clock input CLK 216 is low the signal on output node Q 208 will turn on pull-up transistor 230 if output node Q 208 was driven high during the evaluate interval, feeding Vcc back to output node Q 208 through pull-up transistors 230 and 234 to reinforce the node's high state, or will turn on the pull-down transistor 232 if output node Q 208 was driven low during the evaluate phase, feeding ground back to output node Q 208 through pull-down transistors 236 and 232 to reinforce the node's high state. Thus, it should be appreciated that pull-up transistor 230 and pull-down transistor 232 act as an inverter when enabled by either pull-up transistor 234 or pull-down transistor 236 being turned on. That is, when enabled, pull-up transistor 230 switches Vcc to output node 212 responsive to a low signal on the feedback/feed forward node 226 or else pull-down transistor 232 switches ground to the output node 212 responsive to a high signal on the feedback/feed forward node 226.

Likewise, output nodes 218 and 222 of domino sublatches 202 and 204, respectively, are driven to the same state as that of output node Q 208 during the evaluate phase. Thus, the outputs of inverters 220 and 224 also turn on pull-up transistor 230 or pull-down transistor 232 during precharge, which effectively inverts the output of inverter 228, to reinforce the state of output node Q 208. That is, with data high and clock low during precharge, pull-up transistor 238 and pull-down transistor 240 are turned off so that the feedback and feed forward signals on feedback/feed forward node 226 can reinforce the state of output node Q 208.

The above described arrangement provides the advantage of improved immunity to noise on output node Q 208. That is, the combination of the two feed forward paths through domino sublatches 202 and 204 and their respective inverters 220 and 224, and the feedback path through inverter 228 provide three paths for reinforcing the state of output node Q 208. Consequently, if any one of the output nodes of domino sublatches 202, 204, or 206 is subjected to induced erroneous change of state, the signals of the other two output nodes will prevent pull-up transistor 230 or pull-down transistor 232 of circuit 206 from being switched by the disparate signal, thereby preventing the feedback circuitry 210 from reinforcing the erroneous state so that output node Q 208 does not change to an erroneous state.

It should also be noted that the output nodes of domino sublatches 202, 204, and 206 are preferably physically separated sufficiently so that no two of them are subject to the effects of a single soft-error incident.

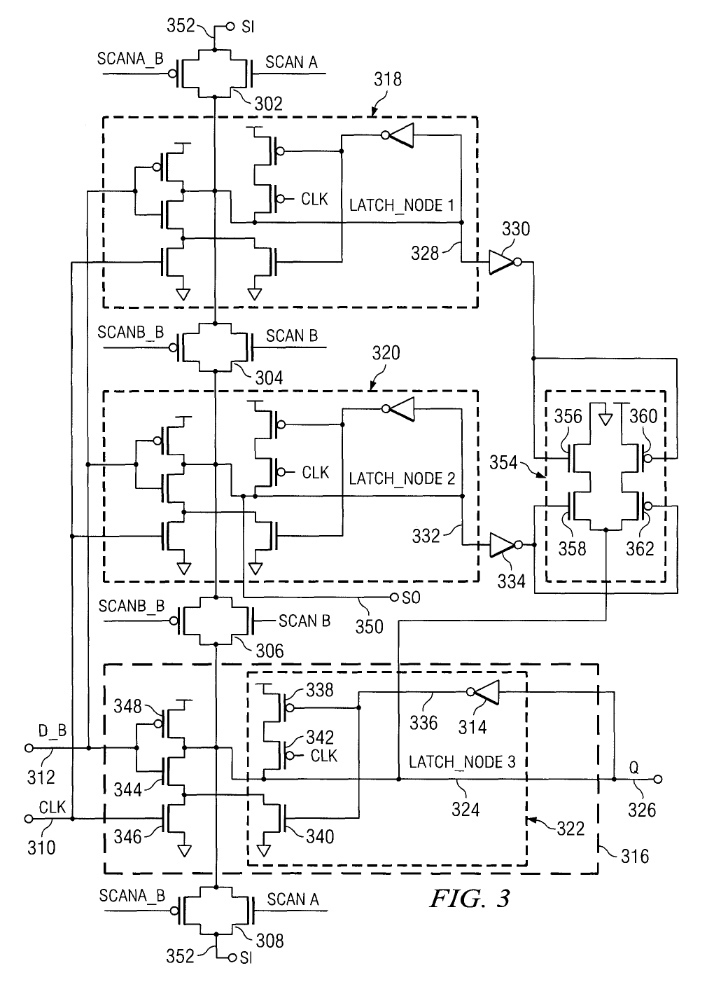

FIG. 3 depicts a domino latch with integrated scan in accordance with an illustrative embodiment of the present invention. Domino latch 300 has two operating modes, a normal operation mode and a scanning mode. In FIG. 3 it is assumed that in the normal operation mode the data signal comes from a preceding logic stage.

As to normal operation, for domino logic such as domino latch 300, during an evaluate phase the first and second scanning control signals SCANA and SCANB are driven low and their complements SCANA_B and SCANB_B are held high so that scanning control switches 302, 304, 306, and 308 are nonconductive and scan data is not written into domino latch 300. Also, during this evaluate phase clock signal CLK 310 goes high and data input D_B 312 is held high or driven low by the preceding logic stage. With clock signal CLK 310 high, domino latch 300 permits data input D_B 312 to drive its latch output high or low, as the case may be. Then, during a precharge phase, data input D_B 312 goes high and clock signal CLK 310 goes low. According to the arrangement shown for domino latch 300, with the data and clock signals in their precharge states feedback through inverters such as inverter 314 explicitly shown in sublatch 316 keep domino latch 300 output at the high or low state to which it was driven during evaluation, as the case may be, regardless of whether the output was driven high or low during evaluation.

In contrast, during the scanning mode of operation of domino latch 300 the first and second scanning control signals SCANA and SCANB are selectively held high and their complements SCANA_B and SCANB_B are driven low according to a particular sequence so that scanning control switches 302, 304, 306, and 308 are conductive and scan data is selectively staged into domino latch 300, as will be further described herein.

Before a further description more related to scanning, those aspects of domino latch 300 which relate more to normal operation of the domino latch 300 are now described. Much of this description relating to normal operation is of greater significance to the related patent application. Accordingly, the following description is somewhat abbreviated by comparison.

Domino latch 300 includes three domino latches 316, 318, and 320, which may be referred to herein as “sublatches,” whereas domino latch 300 may be referred to herein as the “overall” latch. Domino sublatches 316, 318, and 320 are all the same. Circuitry 322 is referred to herein as “feedback/feed forward” circuitry, or more simply as “feedback” circuitry. The outputs of the two feed forward domino sublatches 318 and 320 are coupled to circuit 354. The output of circuitry 354 is coupled to circuitry 322 of domino sublatch 316. Domino sublatch 316, in turn, has its output node 324 coupled to the overall domino latch 300 and output node Q 326. Since output node 324 is directly coupled to the overall output node Q 326 with no device interposed there between, it may be said that output node 324 provides the overall output node Q 326.

Each of domino sublatches 316, 318, and 320 is coupled to the data input D_B 312 and clock signal CLK 310, for receiving signals of the same name. Domino sublatch 318 and output node 328 provides a latch node that is coupled to feedback/feed forward circuitry 322 via inverter 330 and circuitry 354. Inverter 330 may be considered to be part of domino sublatch 318, and may accordingly be referred to herein as an output inverter of domino sublatch 318. Similarly, output node 332 provides a latch node that is coupled to feedback/feed forward circuitry 322 via inverter 334 and circuitry 354, which may be considered to be part of domino sublatch 320.

Circuitry 354 consists of two pull-down transistors 356 and 358 and two pull-up transistors 360 and 362. Domino sublatches 318 and 320 are redundant latches from that of domino sublatch 316. The state of domino sublatch 316 is controlled by the state of domino sublatches 318 and 320 without sublatches 316, 318, and 320 colliding or fighting with one another. FIG. 4 depicts a table of the various output node states and the protection provided by domino sublatches 318 and 320 in accordance with an illustrative embodiment of the present invention. In table 400 at entry 402, pull-down transistors 356 and 358 are ON and failure protection is provided to output node 324. At entry 404, output node 324 is in a corrupt state and is overridden by pull-down transistors 356 and 358. At entry 406, pull-down transistor 358 is OFF, pull-down transistor 356 is ON, and pull-up transistor 362 is ON but has no effect, thus, output node 324 remains 0. At entry 408, pull-down transistor 358 is OFF, pull-down transistor 356 is ON, and pull-up transistor 362 is ON but has no effect, thus, output node 324 remains 1. At entry 410, pull-down transistor 358 is ON, pull-down transistor 356 is OFF, and pull-up transistor 360 is ON but has no effect, thus, output node 324 remains 0. At entry 412, pull-down transistor 358 is ON, pull-down transistor 356 is ON, and pull-up transistor 360 is ON but has no effect, thus, output node 324 remains 1. At entry 414, output node 324 is in a corrupt state and is overridden by pull-up transistors 360 and 362. At entry 416, pull-up transistors 360 and 362 are ON and failure protection is provided to output node 324. Circuitry 354 contends the state change for one inverter stage delay, however, the illustrative embodiment provides for soft error rate protection and not performance.

The internal circuitry of domino sublatch 316 is shown in FIG. 3 to reveal the location of the feed forward connection of the outputs of inverters 330 and 334 to feedback/feed forward node 336 within circuitry 322, and to show the interrelationship and operation of various parts. The binary output signal from output node Q 326 is fed back by circuitry 322 through inverter 314, which has its output coupled to feedback/feed forward node 336 that is common to the gates of pull-up transistor 338 and pull-down transistor 340. In this manner, during the precharge interval when data input D_B 312 is high and clock signal CLK 310 is low the signal on output node Q 326 will turn on pull-up transistor 338 if output node Q 326 was driven high during the evaluate interval, feeding Vcc back to output node Q 326 through pull-up transistors 338 and 342 to reinforce the node's high state, or will turn on pull-down transistor 340 if the output node Q 326 was driven low during evaluate, feeding ground back to output node Q 326 through pull-down transistors 344 and 340 to reinforce the node's low state. Thus, it should be appreciated that pull-up transistor 338 and pull-down transistor 340 act as an inverter when enabled by either pull-up transistor 342 or pull-down transistor 344 being turned on. That is, when enabled, pull-up transistor 338 switches Vcc to the output node 324 responsive to a low signal on the feedback/feed forward node 336 or else pull-down transistor 340 switches ground to output node 324 responsive to a high signal on feedback/feed forward node 336.

The combination of the two feed forward paths through domino sublatches 318 and 320 and their respective inverters 330 and 334, and the feedback path through inverter 314 provide three paths for reinforcing the state of the output node Q 326. Consequently, if any one of the output nodes of circuits 316, 318, or 320 is subjected to an induced erroneous change of state, the signals of the other two output nodes will restore the correct value of output node Q 326 together with circuit 354.

With regard to scanning aspects of domino latch 300, output node 332 of the middle sublatch, domino sublatch 320, provides a scanning output SO 350 for domino latch 300. Domino latch 300 also has four scanning-mode control switches. The first scanning-mode control switch 302 consists of a pair of NFET/PFET passgates. Scanning-mode control switch 302 has one set of conducting electrodes of the set of FET's coupled to the latch node, i.e., output node 328 of domino sublatch 318. Scanning-mode control switch 302 receives a scan data input signal SI 352 on the other set of conducting electrodes of the set of FET's and receives a first scanning control signal SCANA, and its complement SCANA_B, on the gates of the FET's. Scanning-mode control switch 302 selectively receives the scan data conductively to output node 328, according to the control signals asserted on the gates of scanning-mode control switch 302.

Domino latch 300 also has a second scanning-mode control switch 304, also consisting of a pair of NFET/PFET passgates. Scanning-mode control switch 304 couples output node 328 of domino sublatch 318 conductively to output node 332 of domino sublatch 320, according to a second scanning control signal SCANB and its complement SCANB_B asserted on the gates of scanning-mode control switch 304.

Likewise, domino latch 300 has a third scanning-mode control switch 306, also consisting of a pair of NFET/PFET passgates. In similar fashion, scanning-mode control switch 306 couples output node 332 of domino sublatch 320 conductively to output node 324 of domino sublatch 316, according to control signals SCANB and SCANB_B asserted on the gates of scanning-mode control switch 306.

Finally, domino latch 300 has a fourth scanning-mode control switch 308 consisting of a pair of NFET/PFET passgates. Scanning-mode control switch 308 has one set of conducting electrodes of the set of FET's coupled to output node 324 of domino sublatch 316. Scanning-mode control switch 308 receives a scan data input signal SI 352 on the other set of conducting electrodes of the set of FET's and receives the first scanning control signal SCANA and its complement SCANA_B on the gates of the FET's. Scanning-mode control switch 308 selectively transmits the scan data conductively to the output node 324, according to the control signals asserted on the gates of scanning-mode control switch 308.

The arrangement of FIG. 3 is subject to scanning operation as follows. During the scanning operation clock signal CLK 310 goes low and data input D_B 312 is held high. Referring to domino sublatch 316, it may be seen that with these signal states for clock signal CLK 310 and data input D_B 312, output node 324 may be either driven to a low state or held at a high state through a scanning-mode control switch 308 or 306 and circuitry 322 will reinforce that state, tending to latch the state, either by turning on pull-up transistor 338 or pull-down transistor 340, as the case may be.

As is conventional, scanning data into domino latch 300 is done in two phases. For domino latch 300, the first phase is referred to as the “SCANA” scan clock phase, and the second phase is the “SCANB” scan clock phase. According to one sequence for scanning in data, in the first phase the first scanning-mode control signal SCANA is asserted, and its complement SCANA_B is deasserted, and the second scanning-mode control signal SCANB is deasserted, and its complement SCANB_B is asserted, thereby turning on scanning-mode control switch 302 and scanning-mode control switch 308, which conductively couples the scan data input signal SI 352 to output nodes 328 and 324, which latch and hold the data. Then, in the second phase, the first scanning-mode control signal SCANA is deasserted (complement asserted) and the second scanning-mode control signal SCANB is asserted (complement deasserted), which turns on scanning-mode control switches 304 and 306 and conductively couples to output node 332 the data latched in output nodes 328 and 324. At this point, after the SCANB phase of scanning, the data scanned in may be read at the scanning output SO 350.

Thus, the illustrative embodiments of the present invention provide a latch that provides soft error rate protection with integrated scan capability and collision avoidance. The latch has a latch output node, a first sublatch, a second sublatch, and a third sublatch. The first, second, and third sublatches have respective input circuitry, output nodes, and feedback circuitry coupled to respective output nodes for reinforcing an output signal of the respective sublatches. The sublatches are operable to receive a data signal at their respective input circuitry and responsively generate binary-state output signals on their respective output nodes. The third output node is coupled to the latch output node. The first and second output nodes are respectively connected such that, if an output of the third sublatch changes, the first and second sublatches force the third sublatch to have a same output as the first and second sublatch. This “forced” change reduces the soft error rate in the latch and the output signal of the latch output node is restored without the first, second and third sublatches colliding. A number of scanning-mode control switches are also provided, which are coupled to sublatches for scanning data into the latch.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

The above disclosure has been presented for purposes of illustration and is not intended to be exhaustive or to limit the invention to the form disclosed. A preferred embodiment has been disclosed. Many additional aspects, modifications and variations are also contemplated and are intended to be encompassed within the scope of the following claims.

What is claimed is:

1. A latch comprising:
a latch output node;
a first sublatch, wherein the first sublatch has first input circuitry, a first output node coupled to the first input circuitry, and a first feedback circuitry coupled to the first output node for reinforcing an output signal of the first sublatch;
a second sublatch, wherein the second sublatch has second input circuitry, a second output node coupled to the second input circuitry, and a second feedback circuitry coupled to the second output node for reinforcing an output signal of the second sublatch;
a third sublatch, wherein the third sublatch has third input circuitry, a third output node coupled to the third input circuitry, and a third feedback circuitry coupled to the third output node for reinforcing an output signal of the third sublatch;
wherein the first, second, and third sublatches are operable to receive a data signal at their respective input circuitry and responsively generate binary-state output signals on their respective output nodes, and wherein at least the third output node is coupled to the latch output node and the first and second output nodes are respectively connected such that if an output of the third sublatch changes, the first and second sublatches force the third sublatch to have a same output as the first and second sublatch, wherein a soft error rate in the latch is reduced and wherein the output signal of the latch output node is restored without the first, second and third sublatches colliding; and
a number of scanning-mode control switches coupled to ones of the sublatches for scanning data into the latch.

2. The latch of claim 1, wherein the scanning-mode control switches comprise:
a first scanning-mode control switch having a first conducting electrode coupled to the output node of one of the sublatches, a second conducting electrode for receiving scan data from a data source external to the latch, and a gate electrode for receiving a scanning control signal; and
second and third scanning-mode control switches interconnecting the first sublatch output node to the second sublatch output node and the second sublatch output node to the third sublatch output node, respectively, the second and third scanning-mode control switches having respective gate electrodes arranged for receiving a different scanning control signal than that of the first scanning-mode control switch.

3. The latch of claim 1, wherein the scanning-mode control switches comprise:
a first scanning-mode control switch having a first conducting electrode coupled to the output node of the first sublatch, a second conducting electrode coupled to the output node of the second sublatch, and a gate electrode for receiving a first scanning control signal; and
a second scanning-mode control switch having a first conducting electrode coupled to the output node of the second sublatch, a second conducting electrode coupled to the output node of the third sublatch, and a gate electrode for receiving the first scanning control signal.

4. The latch of claim 3, wherein the scanning-mode control switches comprise:
a third scanning-mode control switch having a first conducting electrode coupled to the output node of one of the sublatches, a second conducting electrode for receiving scan data from a data source external to the latch, and a gate electrode for receiving a second scanning control signal.

5. The latch of claim 4, wherein the first conducting electrode of the third scanning-mode control switch is coupled to the output node of the first or third one of the sublatches.

6. The latch of claim 5, wherein the first conducting electrode of the third scanning-mode control switch is coupled to the first one of the sublatches and the scanning-mode control switches comprise:
a fourth scanning-mode control switch having a first conducting electrode coupled to the output node of the third one of the sublatches, a second conducting electrode coupled for receiving or transmitting scan data from or to a data source external to the latch, and a gate electrode for receiving a second instance of the control signal received by the third scanning-mode control switch.

7. The latch of claim 5, wherein the first conducting electrode of the third scanning-mode control switch is coupled to the third one of the sublatches and the scanning-mode control switches comprise:
a fourth scanning-mode control switch having a first conducting electrode coupled to the output node of the first one of the sublatches, a second conducting electrode coupled for receiving or transmitting scan data from or to a data source external to the latch, and a gate electrode for receiving a second instance of the control signal received by the third scanning-mode control switch.

8. The latch of claim 1, wherein the third output node is coupled to the first and second output nodes through an output restore circuit, where the output restore circuit comprises:
a first pull-down transistor and a first pull-up transistor connected to the first output node; and
a second pull-down transistor and a second pull-up transistor connected to the second output node,
wherein the first pull-down transistor is coupled to the second pull-down transistor,
wherein the first pull-up transistor is coupled to the second pull-up transistor, and
wherein the second pull-down transistor is also coupled to the second pull-up transistor and to the third output node.

9. The latch of claim 1, wherein the first pull-up transistor, second pull-up transistor, first pull-down transistor, and second pull-don transistors are field-effect transistors.

10. The latch of claim 2, wherein the first output node of the first sublatch is coupled to a first input of a restore circuit, wherein the second output node of the second sublatch is coupled to a second input of the restore circuit, and wherein the third output node of the third sublatch is coupled to an output of the restore circuit.

11. The latch of claim 2, wherein the sublatches include domino sublatches.

12. The latch of claim 2, wherein the sublatches include static sublatches.

13. The latch of claim 6, wherein the first output node of the first sublatch is coupled to a first input of a restore circuit, wherein the second output node of the second sublatch is coupled to a second input of the restore circuit, and wherein the third output node of the third sublatch is coupled to a output of the restore circuit.

14. The latch of claim 6, wherein the sublatches include domino sublatches.

15. The latch of claim 6, wherein the sublatches include static sublatches.

16. A latch comprising:
an output node;
first, second, and third sublatches, wherein the sublatches each have input circuitry, an output node coupled to the sublatch's input circuitry and feedback circuitry coupled to the sublatch's output node for reinforcing an output signal of the sublatch, and the sublatches are operable to receive a data signal at their respective input circuitry and responsively generate binary-state output signals on their respective output nodes, and
wherein the output node of at least the third sublatch is coupled to the latch output node and the output nodes of the first and second sublatches are respectively connected through a restore circuit in the latch such that, if the output of the third sublatch changes, the first and second sublatches force the third sublatch to have the same output as the first and second sublatch thereby reducing the soft error rate and ensure the output signal of the latch output node is restored without the first, second, and third sublatches colliding, wherein the first output node of the first sublatch is coupled to a first input of a restore circuit, wherein the second output node of the second sublatch is coupled to a second input of the restore circuit, and wherein the third output node of the third sublatch is coupled to a output of the restore circuit;
a first scanning-mode control switch having a first conducting electrode coupled to the output node of the first sublatch, a second conducting electrode for receiving or transmitting scan data from or to a data source external to the latch, and a gate electrode for receiving a scanning control signal;
second and third scanning-mode control switches interconnecting the first sublatch output node to the second sublatch output node and the second sublatch output node to the third sublatch output node, respectively, the second and third scanning-mode control switches having respective gate electrodes arranged for receiving a different scanning control signal than that of the first scanning-mode control switch; and
a fourth scanning-mode control switch having a first conducting electrode coupled to the output node of the third sublatch, a second conducting electrode coupled for receiving or transmitting scan data from or to a data source external to the latch, and a gate electrode for receiving a second instance of the control signal received by the first scanning-mode control switch, wherein the first and second sublatches have their output nodes coupled to the third sublatch's feedback circuitry and the sublatches include domino sublatches, wherein the first and second sublatches are not coupled to the third sublatch by resistors and the first, second and third sublatches are not coupled to a common output inverter.

17. A method of operating a latch, the method comprising the steps of:
a) operating the latch in a normal mode of operation, including the steps of:
a1) receiving a data signal at input circuitry of first, second, and third sublatches and responsively generating binary-state sublatch output signals on output nodes of the respective sublatches;
a2) feeding the output signal of the third sublatch to an output node for the overall latch; and
a3) feeding the output signals of the first and second sublatches in the latch through a restore circuit such that, if the output of the third sublatch changes, the first and second sublatches force the third sublatch to have the same output as the first and second sublatch thereby reducing the soft error rate and ensure the output signal of the latch output node is restored without the first, second, and third sublatches colliding, wherein the first output node of the first sublatch is coupled to a first input of a restore circuit, wherein the second output node of the second sublatch is coupled to a second input of the restore circuit, and wherein the third output node of the third sublatch is coupled to a output of the restore circuit;
b) operating the latch in a data scanning mode of operation, including the steps of:
b1) turning on at least a first scanning-mode control switch in a first phase of a data scanning sequence, wherein turning on the first scanning-mode control switch conductively couples scanning data to one of the sublatch output nodes for holding the data during the first phase; and
b2) turning on at least one other scanning-mode control switch in a second phase of the data scanning sequence, wherein turning on the at least one other scanning-mode control switch conductively shifts the scanning data to an output node of another one of the three sublatches.

18. The method of claim 17, wherein step b1) includes turning on, in the first phase of the data scanning sequence, the first scanning-mode control switch and a second scanning-mode control switch coupled respectively to the output nodes of the first and third sublatches, and step b2) includes turning on, in the second phase of the data scanning sequence, a third and fourth scanning-mode control switch respectively coupling the first and second sublatches and the third and second sublatches.

19. The method of claim 17, wherein b1) includes turning on, in the first phase of the data scanning sequence, the first scanning-mode control switch coupled to the output node of one of the first and third sublatches, and not turning on any scanning-mode control switch coupled to the other one of the first and third sublatches, and step b2) includes turning on, in the second phase of the data scanning sequence, a third and fourth scanning-mode control switch respectively coupling the first and second sublatches and the third and second sublatches.

20. The method of claim 17, wherein all the sublatches of the latch are used throughout both the scanning and normal modes of operation.
